(19) United States
(12) Patent Application Publication
(10) Pub. No.: US 2026/0299231 A1
(43) Pub. Date: Oct. 1, 2026

(54) INTEGRATED OPTICAL ASSEMBLY

(71) Applicant: Lumentum Technology UK Limited, NORTHAMPTONSHIRE (GB)

(72) Inventors: Colin SMITH, Paignton (GB); Samuel Justin JONES, Paignton (GB); Wenfei HU, Paignton (GB)

(21) Appl. No.: 19/230,984

(22) Filed: Jun. 6, 2025

Related U.S. Application Data
(60) Provisional application No. 63/778,124, filed on Mar. 26, 2025.

(51) Int. Cl. G02B 6/42; H10W 90/00

(52) U.S. Cl. CPC G02B 6/4281; G02B 6/4271; H10W 90/00; G02B 6/4215

(57) ABSTRACT

In some implementations, an optical module structure includes a unified packaging structure. For example, the unified packaging structure may comprise a set of layers, such as a first subset of layers comprising a printed circuit board (PCB) structure and a second subset of layers comprising multiple sidewalls of an optical sub-assembly (OSA) structure. Additionally, one or more optical chips may be enclosed within the multiple sidewalls of the OSA structure. For example, the one or more optical chips may be electrically connected to the PCB structure via a first set of electrical interconnects, and the PCB structure may provide a second set of electrical interconnects through the multiple sidewalls of the OSA structure to the one or more optical chips.

### CROSS-REFERENCE TO RELATED APPLICATION

This Patent Application claims priority to US Patent Application No. 63/778,124, filed on Mar. 26, 2025, and entitled “INTEGRATED OPTICAL ASSEMBLY.” The disclosure of the prior Application is considered part of and is incorporated by reference into this Patent Application.

### TECHNICAL FIELD

The present disclosure relates generally to optical module structures and to unified packaging structures.

### BACKGROUND

An optical assembly may integrate various components to facilitate the transmission and reception of optical signals. One component in such assemblies may be an optical sub-assembly (OSA), which may be a structure that includes one or more components responsible for converting electrical signals into optical signals, and vice versa. The OSA may include optical elements such as lasers, photodetectors, and lenses. Another component within the optical assembly may be a printed circuit board (PCB). The PCB may serve as the foundational platform that electrically connects and mechanically supports the OSA and other electronic components. The PCB may achieve such electrical connections by utilizing conductive tracks, pads, and other features etched from conductive sheets laminated onto a non-conductive substrate.

### SUMMARY

In some implementations, an optical module structure includes a unified packaging structure that comprises a set of layers; a first subset of layers of the set of layers comprising a printed circuit board (PCB) structure; a second subset of layers of the set of layers comprising multiple sidewalls of an optical sub-assembly (OSA) structure; and one or more optical chips enclosed within the multiple sidewalls of the OSA structure, wherein: the one or more optical chips are electrically connected to the PCB structure via a first set of electrical interconnects, and the PCB structure providing a second set of electrical interconnects through the multiple sidewalls of the OSA structure to the one or more optical chips.

In some implementations, a method of manufacturing a unified packaging system includes forming a first set of layers that comprise a PCB structure of the unified packaging structure; forming a second set of layers that comprise multiple sidewalls of an OSA structure of the unified packaging structure, wherein one or more optical chips are enclosed within the multiple sidewalls of the OSA structure; providing, via a first set of electrical interconnects, an electrical connection from the one or more optical chips to the PCB structure; and providing, via a second set of electrical interconnects, an electrical connection through the multiple sidewalls of the OSA structure to the one or more optical chips.

In some implementations, a unified packaging structure includes a base; a high-speed electrical interface and a low-speed electrical interface that are both formed from a first set of layers; multiple sidewalls that are formed from a second set of layers; and a lid, wherein: one or more high-speed components and one or more low-speed components are attached to the first set of layers, the base, the multiple sidewalls, and the lid form one or more OSA structures that enclose one or more optical chips, the one or more optical chips are electrically connected to the first set of layers via first a set of electrical interconnects, and the first set of layers providing a second set of electrical interconnects through the multiple sidewalls of the OSA structure to the one or more optical chips.

In some implementations, an integrated optical assembly includes a first set of layers comprising a PCB structure; a second set of layers comprising multiple sidewalls of an OSA structure; and one or more optical chips enclosed within the multiple sidewalls of the OSA structure, wherein: the one or more optical chips are electrically connected to the PCB structure via a first set of electrical interconnects, and the PCB structure providing a second set of electrical interconnects through the multiple sidewalls of the OSA structure to the one or more optical chips.

### BRIEF DESCRIPTION OF THE DRAWINGS

FIG. 1 shows three-dimensional (3D) views of various configurations of a unified packaging structure.

FIG. 2 shows a 3D view and a side-view of a unified packaging structure.

FIG. 3 shows an exploded 3D view of a unified packaging structure.

FIG. 4 shows cross-sectional view of an optical subassembly (OSA) structure of a unified packaging structure.

FIG. 5 shows a top-view of an external housing that includes a unified packaging structure.

FIG. 6 shows a side-view of a unified packaging structure that includes multiple printed circuit board (PCB) structures.

FIG. 7 is a flowchart of an example process associated with manufacturing an integrated optical assembly.

### DETAILED DESCRIPTION

The following detailed description of example implementations refers to the accompanying drawings. The same reference numbers in different drawings may identify the same or similar elements.

Optical assemblies may be components in high-speed transceiver modules, responsible for converting electrical signals into optical signals and vice versa for transmission and/or reception over fiber optic cables. Optical assemblies may include transmitter optical assemblies, receiver optical assemblies, and/or transmitter/receiver optical assemblies. A transmitter optical assembly may be a component in transceiver modules responsible for converting electrical signals into optical signals for transmission over fiber optic cables. A transmitter optical assembly may include a laser diode, driver circuitry, and various optical components such as lenses and isolators. A receiver optical assembly may perform the inverse function of optical transmitter assemblies, converting incoming optical signals back into electrical signals that can be processed by the transceiver module. These receiver optical assemblies may include a photodiode, transimpedance amplifier (TIA), and/or other optical components such as filters and lenses. A transmitter/receiver optical assembly may combine both transmitting and receiving functions into a single optical module, offering a more integrated solution for high-speed transceiver modules.

An optical assembly can include one or more optical sub-assemblies (OSAs) to handle various functions such as transmitting, receiving, and signal processing within a single optical module. For example, an OSA may be a compact, integrated unit that can include optical components such as lasers, photodiodes, lenses, and/or driver or amplifier circuits. By incorporating multiple OSAs, an optical assembly can efficiently manage multiple optical channels or functions, enhancing the overall capability and performance of the transceiver module.

In some designs, OSAs may be connected to a printed circuit board (PCB). For example, a PCB may be a flat, board that mechanically supports and electrically connects electronic components using conductive pathways, tracks, and/or signal traces etched from conductive sheets bonded onto a non-conductive substrate. The connection of an OSA to the PCB may be achieved using soldered joints or flexible circuits (e.g., flexi connections). Soldered connections may involve attaching the optical assembly directly to the PCB using solder, which provides a robust and reliable connection, but can be challenging to execute due to the precision required. Flexi connections, on the other hand, may use flexible circuits that can bend and conform to the layout of the module, allowing for more versatile placement of components. However, the connecting of OSAs to module PCB substrates presents a number of different problems and challenges. For instance, flexi connections may be used to attach the OSA to the PCB, and these flexible circuits may require bonding at both sides (e.g., through a soldering processes) which may utilize specialized equipment and skills. Additionally, flexi connections can lead to connection issues because they are relatively fragile and susceptible to mechanical stress, such as bending or vibration, which can cause cracks or breaks over time. Additionally, the alignment and bonding for flexi connections increases the risk of poor solder joints or intermittent electrical contact. Accordingly, the use of soldered joints and/or flexible circuits to electrically connect OSAs and PCBs can lead to connection issues, potential reliability concerns, and may also result in the flexible circuits taking up additional space within both the optical assembly module and the OSA. Furthermore, interfacing the high-speed signals (such as radio frequency (RF), or other types of electrical signals) from the OSA to the module PCB can introduce performance limitations, such as restricted bandwidth and increased signal loss, which may reduce the speed and efficiency of the transceiver module. Addressing these challenges of electrical connections between the PCB and OSAs may therefore improve RF bandwidth (e.g., enabling higher speed devices) and save space within the optical assembly module, supporting smaller form factors, and simplifying the assembly process (e.g., making the manufacturing process of optical assemblies easier, faster, and/or less expensive).

Some implementations described herein provide integrating one or more OSAs directly within the PCB to create a combined assembly. Such a combined assembly may be referred to herein as a “unified packaging structure,” or other provided names. In some examples, the unified packaging structure may be a single substrate/part for both an OSA structure and a PCB structure. For example, the unified packaging structure may include a set of layers, where a first subset of layers forms the PCB structure and a second subset of layers forms multiple sidewalls of the OSA structure. In some aspects, one or more optical chips (or other electronic components) may be enclosed within the multiple sidewalls of the OSA structure. Accordingly, the one or more optical chips may be electrically connected to the PCB structure via a first set of electrical interconnects (e.g., one or more wire bonds, one or more flexible circuits, or one or more flip chip solders within the multiple sidewalls of the OSA structure). In some aspects, the PCB structure may include a second set of electrical interconnects (e.g., electrical traces) through the multiple sidewalls of the OSA structure. For example, the second set of electrical interconnects may be designed to connect one or more optical components, one or more photonic integrated circuits (PiCs), and/or one or more RF integrated circuits (ICs) on either side of the multiple sidewalls.

The integration of the OSA structure and PCB structure into a unified packaging structure may reduce the number of parts and the complexity of the assembly process. Additionally, the unified packaging structure may improve one or more electrical interfaces (e.g., an RF interface and/or a direct current (DC) interface) between the OSA structure and the PCB structure, which may achieve higher bandwidths and increased band rates. Additionally, the fewer components and simpler assembly processes associated with the unified packaging structure may result in lower manufacturing expenses, leading to cost reductions. Further, the unified packaging structure may enhance thermal management based on better heat dissipation, and the overall connection reliability between the OSA structure and PCB structure may be improved, resulting in faster and more reliable optical processes.

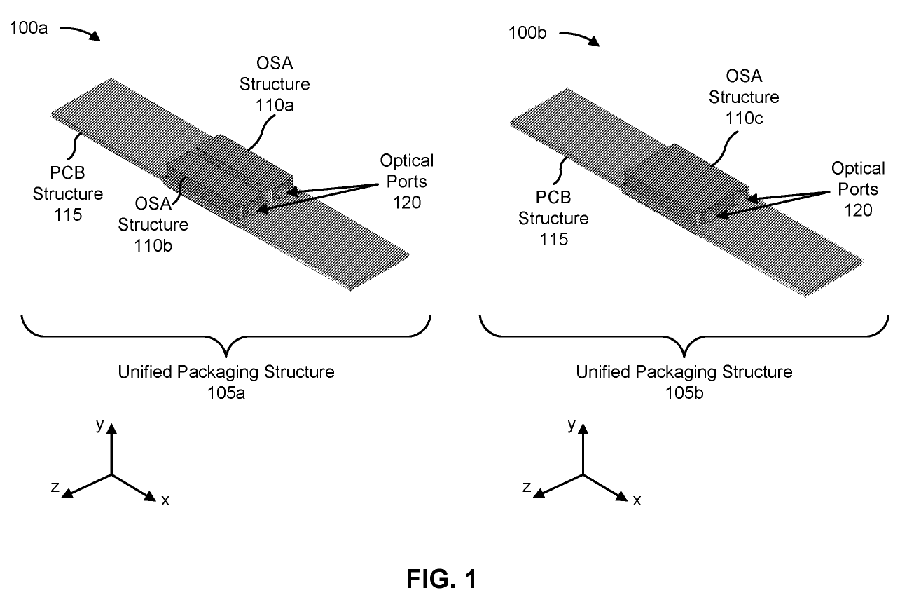

FIG. 1 shows three-dimensional (3D) views 100a and 100b of various configurations of a unified packaging structure 105. For example, a unified packaging structure 105a includes multiple OSA structures 110 (e.g., OSA structure 110a and 110b) and a PCB structure 115. Alternatively, a unified packaging structure 105b includes a single OSA structure 110 (e.g., an OSA structure 110c) and the PCB structure 115.

As described herein, the unified packaging structure may include a set of layers. For example, a first subset of layers of the set of layers may comprise (e.g., form) the PCB structure 115. The PCB structure 115 may serve as the foundational platform for mechanically supporting and electrically connecting the various electronic and optoelectronic components within an optical module or assembly. For instance, the PCB structure 115 may be constructed from a non-conductive substrate, on which conductive pathways (e.g., electrical traces) are etched or printed to form the electrical circuits. The first subset of layers that form the PCB structure 115 may form multiple stacked layers, with each layer containing a respective set of electrical traces. In some examples, the first subset of layers are laminated together, and electrical connections between the layers are made (e.g., using plated-through holes or vias), allowing for compact and complex circuit designs. This multilayer structure enables efficient routing of high-speed signals, power, and/or ground connections throughout the PCB structure 115, supporting the dense integration and advanced functionality required in high-performance transceiver modules. Further description of the PCB structure 115 (e.g., including material and placement within the unified packaging structure 105) are provided elsewhere herein.

Additionally, a second subset of layers of the set of layers comprise (e.g., form) multiple sidewalls of an OSA structure 110. As shown in FIG. 1, the second subset of layers that form the sidewalls of the OSA structure 110c are attached to the first subset of layers that form the PCB structure 115, form a singular/unified structure (e.g., the unified packaging structure 105). Additionally, a unified packaging structure 105 that include multiple OSA structures 110 may include separate subsets of layers for each of the OSA structures 110. For example, with reference to the unified packaging structure 105a which comprises a set of layers, a first subset of layers form the PCB structure 115, a second subset of layers form the multiple sidewalls of the OSA structure 110a, and a third subset of layers form the multiple sidewalls of the OSA structure 110b. Further description of the OSA structure 110 (e.g., including material and placement within the unified packaging structure 105) are provided elsewhere herein.

Additionally, as shown in FIG. 1, the OSA structures 110 include one or more optical ports 120. For example, the OSA structure 110c includes two optical ports 120, while the OSA structure 110a and 110b each include one optical port 120. In other implementations, an OSA structure 110 may include any number of optical ports 120 on one or more sidewalls formed from the second subset of layers. The optical port 120 can be integrated into a sidewall of the OSA structure 110 to provide an interface for coupling optical signals into or out of the OSA structure 110. This optical port 120 may be an aligned opening or receptacle in the sidewall of the OSA structure 110, designed to receive an optical fiber or optical connector. The optical port 120 may be mechanically secured to the sidewall using adhesives, mechanical fasteners, and/or by being molded as part of the OSA structure 110 sidewall itself. In some implementations, the optical port 120 may also include alignment features or guide pins that precisely position the fiber or connector relative to the internal optical components (such as lenses or photodiodes) inside the OSA structure 110. Additionally, the interface between the optical port 120 and the sidewall may be sealed to prevent dust or contaminants from entering the OSA structure 110, which helps maintain signal integrity and long-term reliability. Accordingly, the one or more optical ports 120 may connect an optical signal to at least one optical chip enclosed within the multiple sidewalls of the OSA structure 110 (e.g., an optical chip 405 as described elsewhere herein). For instance, each optical port 120 may include an optical fiber that facilitates the optical signal through the sidewall to the at least one optical chip.

Other examples may differ from what is shown and described with regard to FIG. 1.

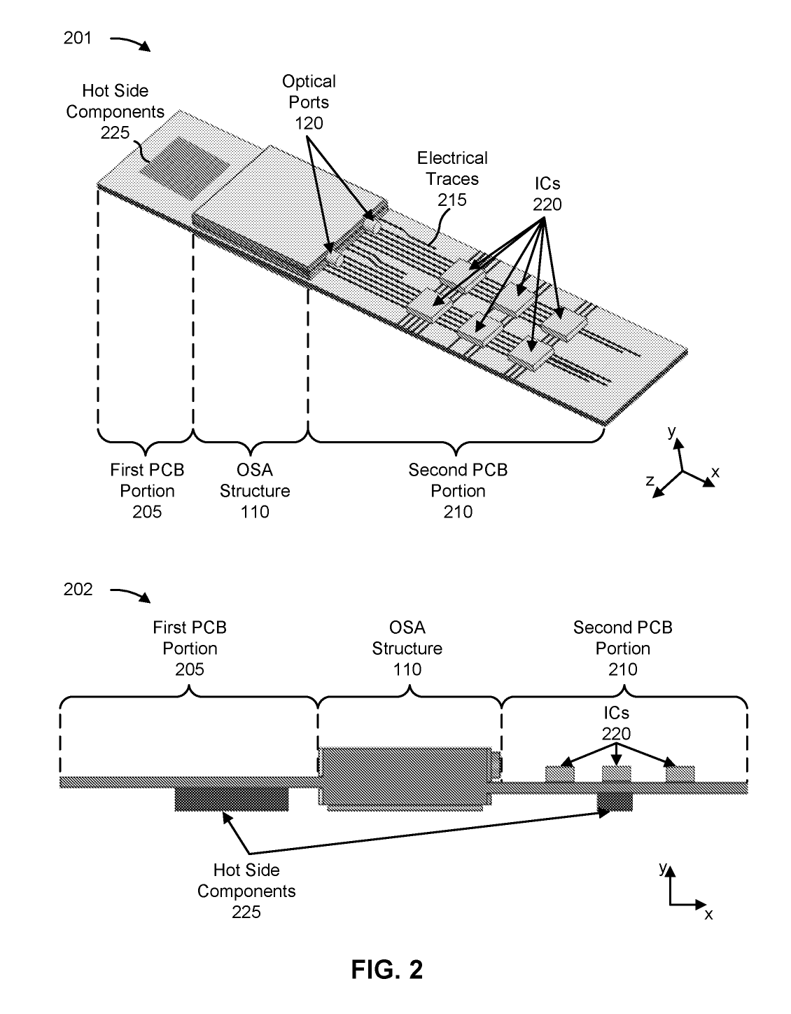

FIG. 2 shows a 3D view 201 and a side-view 202 of a unified packaging structure. In some implementations, the unified packaging structure shown in FIG. 2 may implement or be implemented by one or more aspects of the unified packaging structure 105a and/or 105b. For example, FIG. 2 shows a unified packaging structure 105 which includes a single OSA structure 110 (e.g., unified packaging structure 105b). However, in other implementations, aspects provided herein may be implemented and/or applied for a unified packaging structure that includes multiple OSA structures (e.g., the unified packaging structure 105a).

In some implementations, one or more layers of the set of layers that comprise the unified packaging structure 105 may be made of alumina. For example, alumina can be layered with metallized tracking to create a 2D circuit structure. This involves precise layering and bonding techniques to ensure the integrity of the circuits across multiple layers (e.g., laminated layers). The process may also include high-temperature sintering to achieve the desired mechanical strength and stability. In some examples, the set of layers of the unified packaging structure 105 may comprise a lower-cost PCB material (such as flame retardant (FR) 4 (FR-4)). For instance, FR-4 may be a flame-retardant epoxy resin. In some examples, the set of layers of the unified packaging structure 105 may comprise a high temperature co-fired ceramic (HTCC) material. For example, HTCC is a ceramic-based substrate used to fabricate dense, multilayer electronic circuits capable of withstanding operating temperatures above a temperature threshold. To form HTCC, ceramic materials such as alumina may be mixed with binders and then co-fired with metal pastes (such as tungsten or molybdenum) at high temperatures (e.g., approximately 1600 degrees Celsius (° C)) to form multilayer structures. In some examples, the HTCC material may include 92-96% alumina or aluminum nitride (AlN). In some examples, the set of layers of the unified packaging structure 105 may comprise a low-temperature co-fired ceramic (LTCC) material. For example, LTCC is multilayer ceramic where the ceramic and conductive materials (e.g., silver, gold, and/or copper) are co-fired at lower temperatures compared to HTCC (e.g., approximately 850° C). This lower temperature allows the integration of high-conductivity metals that would oxidize or degrade at HTCC temperatures.

In some implementations, one or more layers of the set of layers of the unified packaging structure 105 may comprise a set of electrical traces 215 (e.g., metallized tracking) which can be connected across and between the set of layers of the unified packaging structure 105. For example, the electrical traces 215 may be conductive pathways that carry electrical signals between components of the unified packaging structure 105. The electrical traces 215 may be comprised of copper (or some other conductive metal or metal alloy) and are etched onto the surface of the PCB structure 115 or embedded within one or more layers of the set of layers of the unified packaging structure 105. Accordingly, the electrical traces 215 enable compact and efficient circuit designs. In some examples, the electrical traces 215 may be an example of “electrical interconnects,” as described herein.

As shown in FIG. 2, the unified packaging structure 105 includes a first PCB portion 205 and a second PCB portion 210. In some implementations, the first PCB portion 205 may be an example of a “high-speed portion” of the PCB structure 115, and the second PCB portion 210 may be an example of a “low-speed portion” of the PCB structure. In some other implementations, the first PCB portion 205 may be an example of a “first low-speed portion” of the PCB structure 115, and the second PCB portion 210 may be an example of a “second low-speed portion” of the PCB structure. In some examples, a “high-speed portion” of the PCB structure 115 may be the section of the PCB structure 115 that includes electrical connections to communicate with one or more components connected to the PCB structure with a data throughput greater than or equal to a throughput threshold (e.g., electrical frequencies and/or data rates that are greater than or equal to 50 megahertz (MHz)). In some examples, a “low-speed portion” of the PCB structure 115 may be the section of the PCB structure 115 that includes electrical connections to communicate with one or more components connected to the PCB structure 115 with a data throughput less than the throughput threshold (e.g., electrical frequencies and/or data rates that are less than 50 MHz).

In some examples, the “high-speed portion” of the PCB structure, may be referred to as an “RF section” of the PCB structure. For instance, if the first PCB portion 205 is the “high-speed portion,” then the first PCB portion 205 may include transmission lines, RF connectors, filters, amplifiers, and/or matching networks, which may be used for maintaining signal integrity. Transmission lines, (such as a microstrip), may be designed to match characteristic impedance and minimize signal loss. RF connectors may enable proper physical connections with minimal reflection. Filters may allow desired frequencies to pass while blocking others, and amplifiers may boost signal strength. Matching networks may optimize impedance matching to increase power transfer. In other words, the high-speed portion (or RF section) may be designed for preserving the integrity of high-frequency signals.

In some examples, the “low-speed portion” of the PCB structure, may be referred to as a “DC section” of the PCB structure. For instance, if the second PCB portion 210 is the “low-speed portion,” then the second PCB portion 210 may manage and/or distribute a DC power supply to various components of the unified packaging structure 105. The low-speed portion may include voltage regulators, capacitors, inductors, and/or power distribution traces designed to enable stable power delivery across one or more components of the unified packaging structure 105. Voltage regulators may be used to convert and stabilize the input voltage to permissible levels for different components, and capacitors and inductors may filter out noise and reduce peak-to-peak variance in the power supply. The layout of the low-speed portion may leverage wide traces and planes to increase current load capabilities and reduce voltage drops. Proper grounding and decoupling techniques may be employed at the low-speed portion to reduce electrical noise and enable reliable operation of the electronic circuits. In other words, the low-speed portion may provide power to multiple active components included in or associated with the unified packaging structure 105.

In some implementations the first PCB portion 205, the second PCB portion 210, and/or the PCB structure 115 may comprise a flexible type circuit. A flexible type circuit (or flexible PCB) may refer to a circuit board comprised of flexible materials (such as polyimide, polyester, or other materials), allowing the flexible type circuit to bend, twist, and/or fold without damaging the attached circuitry and/or electrical components. This flexibility enables the first PCB portion 205, the second PCB portion 210, and/or the PCB structure 115 to fit into compact or irregularly shaped electronic devices.

As shown in FIG. 2, the unified packaging structure 105 includes the OSA structure 110. In some examples, the OSA structure 110 may be an example of an OSA package. For example, the OSA structure 110 may be an encapsulated unit that houses one or more OSA components along with additional elements used for protection, alignment, and/or interfacing with other system components. Additionally, the OSA structure 110 may provide mechanical support, environmental protection, and/or thermal management, enabling one or more optical components (encapsulated inside the OSA structure 110) to operate reliably under various conditions. The OSA structure 110 may include one or more electrical connections and/or interfaces used to integrate and electrically connect the optical components with the rest of the unified packaging structure 105 (e.g., electrical connections/interface to the first PCB portion 205 and/or the second PCB portion 210).

As shown in FIG. 2, the unified packaging structure 105 includes hot side components 225. For example, hot side components 225 may refer to components that generate significant heat during operation (e.g., heat output above a heat threshold). For example, the hot side components 225 may include one or more of a central processing unit (CPU) or a digital signal processor (DSP), among other examples. As shown in FIG. 2, the hot side components may be included in and/or bonded to the first PCB portion 205 and/or the second PCB portion 210. In some other implementations, the hot side components 225 may be optional components that may or may not be included in the unified packaging structure 105.

As shown in FIG. 2, the unified packaging structure 105 includes ICs 220. In some examples, the ICs 220 may be DC ICs. For example, the ICs 220 may include one or more of digital-to-analog converters (DACs), analog-to-digital converters (ADCs), or microprocessors/microcontrollers that handle the processing of digital data. In some implementations, the ICs 220 may be included in and/or bonded to the low-speed portion of the PCB structure 115. In some other implementations, the ICs 220 may be optional components that may or may not be included in the unified packaging structure 105.

Other examples may differ from what is shown and described with regard to FIG. 2.

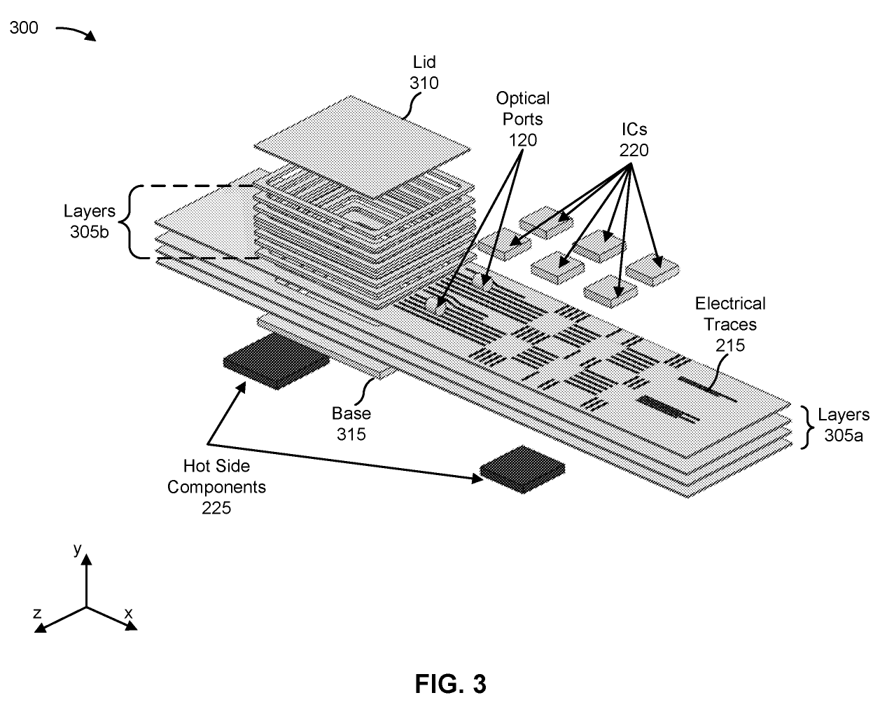

FIG. 3 shows an exploded 3D view 300 of a unified packaging structure. In some implementations, the unified packaging structure 105 shown in FIG. 3 may implement or be implemented by one or more aspects of the unified packaging structure 105a and/or 105b. For example, FIG. 3 shows the set of layers that comprise the unified packaging structure 105 which includes a single OSA structure 110 (e.g., unified packaging structure 105b). However, in other implementations, aspects provided herein may be implemented and/or applied for a unified packaging structure 105 that includes multiple OSA structures (e.g., the unified packaging structure 105a). Additionally, the unified packaging structure 105 of FIG. 3 may include one or more components (provided elsewhere herein) that are attached and/or electrically connected. For instance, as shown in FIG. 3, one or more ICs 220, one or more electrical traces 215, and one or more hot side components 225 are attached to or included as part of the unified packaging structure 105. Additionally, the sidewalls of the OSA structure 110 may include optical ports 120, as described elsewhere herein. For example, an optical port 120 may be one or more of a hermetic fiber feedthrough, a non-hermetic fiber feedthrough, a lens embedded in the wall of the OSA structure 110, a gradient index micro lens (GRIN) embedded in the wall of the OSA structure 110, a non-imaging transmissive material, or a hole, among other examples. As shown in FIG. 3, the unified packaging structure 105 comprises various layers (e.g., one or more layers 305a and one or more layers 305b).

The layers 305a may be described herein as the “first subset of layers” of the unified packaging structure 105. For example, the layers 305a may comprise the PCB structure 115. In some examples, the layers 305a may be one or more of a polymer material (e.g., FR 2 (FR-2) or FR-4 material), an LTCC material, an HTCC material, or thermoplastic material. Additionally, or alternatively one or more of the layers 305a may be embedded and/or etched with a conductive tracking material (e.g., the electrical traces 215). The fabrication of the layers 305a to form the PCB structure 115 begins with the preparation of individual core layers, which may comprise any of the described materials for the layers 305a and may be protected with a conductive material (e.g., copper foil) on both sides. The layers 305a may then be cleaned and coated with a light-sensitive photoresist, which may be exposed to ultraviolet light through a photomask that defines the circuit pattern. The exposed areas are developed away, and the underlying conductive material is etched to form electrical traces 215 on each inner layer. After stripping off the remaining photoresist, these patterned layers may be treated with an oxide or micro-etch process to enhance adhesion. Multiple inner layers may then be stacked together to form the layers 305a. The stack of layers 305a may be pressed and heated in a lamination press, which fuses the layers 305a into a solid, unified board structure. After lamination, a computer numerical control (CNC) drilling process may create vias (e.g., small holes that allow electrical connection between layers). The drilled holes may be chemically cleaned and plated with a thin layer of conductive material using electroless and/or electrolytic plating methods to establish vertical electrical paths. Outer layer patterning follows a similar photoresist and etching process to create external traces and/or pads. This layered fabrication approach allows complex routing of electrical signals through multiple stacked layers of the PCB structure 115.

In some implementations, the layers 305a may be formed via a 3D printing process. The 3D printing process of the layers 305a may involve the additive manufacturing of both the substrate and electrical traces 215 in a layer-by-layer process. The process may begin with a digital PCB structure 115 design, which is converted into a format compatible with the 3D printer. The 3D printer may deposit the insulating substrate material (e.g., a thermoplastic material such as polyimide or epoxy) layer by layer to build the base 315 structure of the PCB structure. Simultaneously or in alternating passes, a conductive ink (e.g., including metallic compounds) may be printed to form the electrical traces 215, pads, and vias. These conductive paths (e.g., the electrical traces 215) may be sintered using heat, ultra-violet (UV) light, and/or a laser to enhance conductivity by solidifying the metal particles into continuous conductive tracks. In some examples, the layers 305a can be built by printing insulating layers between conductive layers, with vertical interconnections formed by printing and curing conductive vias at designated locations. After printing, the layers 305a may undergo post-processing steps such as curing, surface treatment, and/or encapsulation.

The layers 305b may be described herein as the “second subset of layers” of the unified packaging structure 105. For example, the layers 305b may comprise the sidewalls of the OSA structure 110. In some examples, the layers 305b may comprise one or more materials, including one or more of a polymer material (e.g., FR-2 or FR-4), an LTCC material, an HTCC material, a thermoplastic material, a conductive tracking material, a metal, or a metal alloy. Additionally, the fabrication process of layer 305b may be the same as or similar to the fabrication process of layer 305a (e.g., via the preparation of multiple core layers to form a stack of layers or vias in the 3D printing process). That is, the layers 305b may comprise multiple stacked layers that define the multiple sidewalls of the OSA structure. In some other examples, however, the layers 305b may comprise a single layer that defines the multiple sidewalls of the OSA structure 110 (e.g., a monolithic layer that forms the multiple sidewalls of the OSA structure 110).

As shown in FIG. 3 the layers 305b are above the layers 305a. That is, the bottom layer of the layers 305b is attached and/or bonded to the top layer of the layers 305a. In another implementation, however, the layers 305a may be above the layers 305b. That is, the bottom layer of the layers 305a are attached and/or bonded to the top layer of the layers 305b. In another implementation, however, the layers 305a may be between at least a first portion of the layers 305b and a second portion of the layers 305b. For example, the first portion of the layers 305b (e.g., an upper contiguous subset of the layers 305b) may be above the layers 305a such that the bottom layer of the first portion of layers 305b is attached and/or bonded to the top layer of the layers 305a, and the second portion of the layers 305b (e.g., an lower contiguous subset of the layers 305b) may be below the layers 305a such that the bottom layer of the layers 305a is attached and/or bonded to the top layer of second portion of layers 305b.

As shown in FIG. 3, the layers 305a extend outwardly from the multiple sidewalls in a plane that is perpendicular to the multiple sidewalls. For example, the multiple sidewalls (formed by the layers 305b) extend in the y-direction, while the layers 305a extend in the z-x plane. Accordingly, the layers 305a form a platform in the z-x plane, where multiple components (e.g., ICs 220, hot side components 225, among other examples) may be attached and/or electrically connected to the platform.

As shown in FIG. 3, the unified packaging structure 105 further includes a lid 310 and a base 315. In some examples, the lid 310 and the base 315 may be part of the OSA structure 110. The lid 310 may be attached to a top layer of the layers 305b, and a base 315 may be attached to a bottom layer layers 305b or attached to a bottom layer of the layers 305a. Accordingly, the lid 310, the base 315, and the layers 305a (that form the multiple sidewalls define a housing) may enclose one or more optical chips (e.g., optical chip 405, provided herein). Additionally, the lid 310 and the base 315 may be comprised of a metal or metal alloy. In some implementations, the housing formed by the lid 310, the base 315, and the multiple sidewalls may be hermetically sealed. In some other implementations, the housing formed by the lid 310, the base 315, and the multiple sidewalls may be non-hermetic. In some implementations, the lid 310 may be an optional component that may or may not be included as part of the unified packaging structure 105. In some implementations, the lid 310 may be a removable component to provide access to one or more components enclosed within the housing of the OSA structure 110.

Other examples may differ from what is shown and described with regard to FIG. 3.

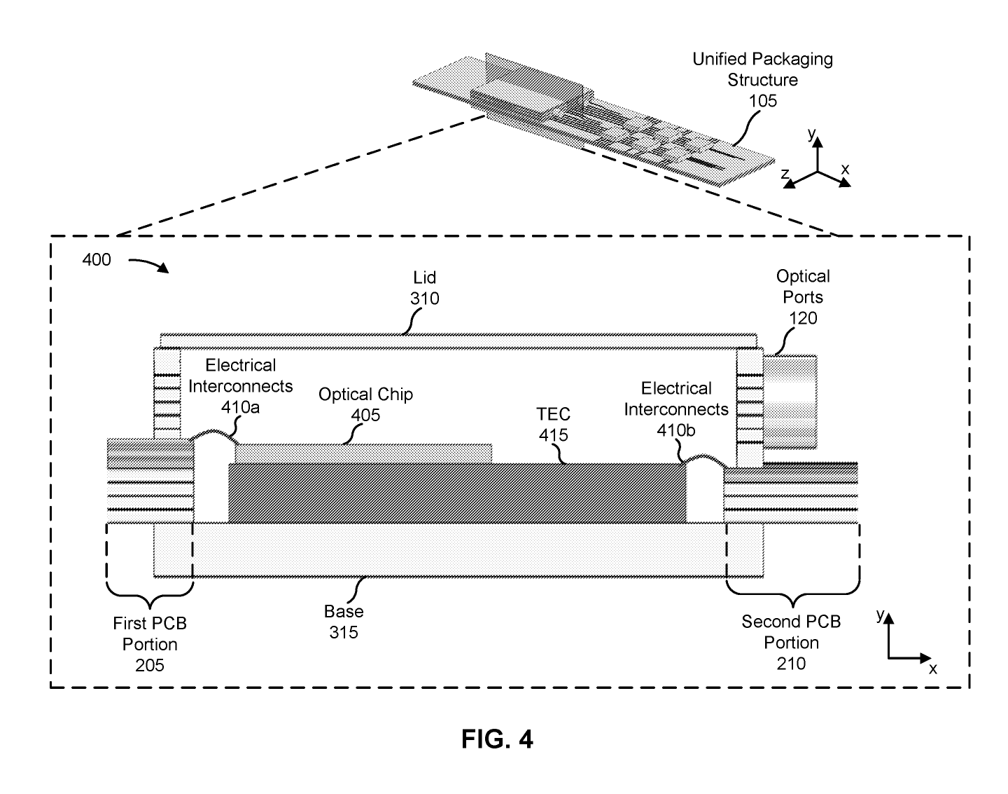

FIG. 4 shows cross-sectional view 400 of an OSA structure of a unified packaging structure. In some implementations, the unified packaging structure 105 shown in FIG. 4 may implement or be implemented by one or more aspects of the unified packaging structure 105a and/or 105b. For example, FIG. 4 shows the unified packaging structure 105 which includes a single OSA structure 110 (e.g., unified packaging structure 105b). However, in other implementations, aspects provided herein may be implemented and/or applied for a unified packaging structure 105 that includes multiple OSA structures 110 (e.g., the unified packaging structure 105a).

As shown in FIG. 4, the cross-sectional view 400 shows the space enclosed by the housing of the OSA structure 110, where the housing comprises the multiple sidewalls, the lid 310, and the base 315. Within the housing the OSA structure 110 there may be one or more optical components. As shown in FIG. 4, the housing encloses an optical chip 405, one or more sets of electrical interconnects 410 (e.g., electrical interconnects 410a and 410b), and a thermoelectric cooler (TEC) 415. Additionally, or alternatively, the housing may enclose one or more other components not shown in FIG. 4 (e.g., optical lenses or collimators for focusing and directing the light, electrical circuitry for controlling the operation of the active elements, and/or fiber alignment structures to enable optical coupling with external fibers or connectors, among other examples).

The optical chip 405 within an OSA structure 110 may be an integrated device designed to perform one or more optical signal processing functions. For instance, the optical chip 405 may incorporate one or more active and/or passive optical elements (such as laser sources, modulators, photodetectors, multiplexers, and/or waveguides) on a single substrate/carrier. The functions of the optical chip 405 may include generating, modulating, routing, and/or detecting optical signals. In some implementations, the optical chip 405 may be capable of both transmitting and receiving optical signals. For instance, on the transmission side, the optical chip 405 can include integrated lasers and modulators that generate and encode data onto light signals, and on the receiver side, the optical chip 405 may include photodetectors and/or electronic circuits that sense incoming light and convert the light into electrical data. In some implementations, the housing of the OSA structure 110 may enclose one or more optical chips 405 capable of performing one or more of the optical operations provided herein.

The TEC 415 may be a type of solid-state device used to control temperature by transferring heat from one side of the device to the other when electrical current is applied. For instance, within the housing of the OSA structure 110, the TEC 415 may maintain the operating temperature of one or more optical chips 405 within a configured range of operating temperatures for the one or more optical chips 405. In some implementations, the TEC 415 may be an optional component that may or may not be included within the housing of the OSA structure 110.

As shown in FIG. 4, the bottom face of the optical chip 405 is attached to the top face of the TEC 415, and the bottom face of the TEC 415 is attached to the base 315. However, in other implementations, the placement of the various components within the housing of the OSA structure 110 may differ. For example, the optical chip 405 may be attached to carrier. A carrier may refer to a substrate and/or platform that provides mechanical support and alignment for the optical chip 405. The carrier may comprise materials with favorable thermal and mechanical properties (such as ceramics, metals, and/or polymers), to ensure stability and effective heat dissipation from the one or more optical chips 405. When an optical chip 405 is attached to a carrier, the carrier serves as the foundation onto which the optical chip 405 is mounted (e.g., mounted using adhesives, solder, and/or bonding techniques). Accordingly the carrier may be attached to the TEC 415 (e.g., to enable heat dissipation from the carrier), and the TEC 415 may be attached to the base 315. Alternatively, in implementations not including the TEC 415, the carrier may be attached directly to the base 315. Alternatively, the first and/or second PCB portions, 205, 210 may extend under the optical chip 405 and the optical chip 405 may be attached directly to a PCB portion (e.g., the first PCB portion 205 and/or second PCB portion 210).

As shown in FIG. 4, the optical chip 405 is electrically connected to the PCB structure 115 via a first set of electrical interconnects 410. For example, a first subset of electrical interconnects 410a may electrically connect the optical chip 405 to the first PCB portion 205 (e.g., a high-speed portion of the PCB structure 115 in aspects of FIG. 4) that is electrically connected to one or more components (e.g., high-speed components such as DSPs, CPUs, among other examples) of an optical module structure that includes the unified packaging structure 105. Additionally, a second subset of electrical interconnects 410b electrically connects the optical chip 405 to the second PCB portion 210 (e.g., a low-speed portion of the PCB structure 115 in aspects of FIG. 4) that is electrically connected to one or more components (e.g., low-speed components such as ICs 220) of the optical module structure that includes the unified packaging structure 105. In some implementations, the first set of electrical interconnects 410 may comprise one or more of one or more wire bonds, one or more flexible circuits, or one or more flip chip solders.

Additionally, the PCB structure 115 may include a second set of electrical interconnects (e.g., the electrical traces 215) that go through the multiple sidewalls of the OSA structure 110 to the optical chip 405. For example, as described herein, the PCB structure 115 may include electrical traces 215 within one or more layers of the first subset of layers that comprises the PCB structure 115. As shown in FIG. 4, the first PCB portion 205 and the second PCB portion 210 include respective sections that are internal to the housing of the OSA structure 110. Accordingly, the electrical interconnects 410a and 410b may connect the optical chip 405 and one or more other components internal to the housing (e.g., the TEC 415) to the electrical traces 215 of the first PCB portion 205 and/or the electrical traces 215 of the second PCB portion 210.

In some examples, the first PCB portion 205 may be coplanar to the second PCB portion 210, where the first PCB portion 205 and the second PCB portion 210 lie within the same geometric plane (e.g., the z-x plane as shown in FIG. 4). In other words, every point of a given layer of the first PCB portion 205 shares the same flat, two-dimensional surface as a given layer of the second PCB portion 210. This alignment ensures there is no vertical offset or overlap between the layers, such that the first PCB portion 205 and the second PCB portion 210 are level with each other. In such examples of coplanarity, the first PCB portion 205 and the second PCB portion 210 may include the same number of layers. Coplanarity may be advantageous in applications such as microelectronics and/or, where precise stacking or alignment may enable proper function.

In some other examples, the first PCB portion 205 may not be coplanar to the second PCB portion 210. For instance, the first PCB portion 205 comprises a first PCB stack from the first subset of layers and the second PCB portion 210 comprises a second PCB stack from the from the first subset of layer. In some examples, non-coplanar means that the first PCB portion 205 and second PCB portion 210 of the PCB structure 115 are not situated within the same flat plane. Instead, these portions are positioned at different heights and/or levels relative to each other (e.g., within the z-x plane shown in FIG. 4), creating a step or offset in the PCB structure 115. This could involve one portion being vertically raised or lowered compared to the other, rather than both lying evenly across a single surface. Additionally, or alternatively, the first PCB portion 205 and the second PCB potion may include a different number of layers from the first subset of layers that form the PCB structure 115. For instance, as shown in FIG. 4, the first PCB portion 205 may be comprised of a first number of layers and the second PCB portion 210 may be comprised of a second number of layers that is less than the first number of layers (e.g., or vice versa in other implementations). Such a design of non-coplanar portions of the PCB structure 115 allows for the separation of different signal types or functionalities (e.g., a high-speed portion comprising a first PCB stack from a subset of layers, and a low-speed portion comprising a second PCB stack from the same subset). This arrangement can help optimize electrical performance or accommodate specific mechanical characteristics within the overall PCB structure 115.

Other examples may differ from what is shown and described with regard to FIG. 4.

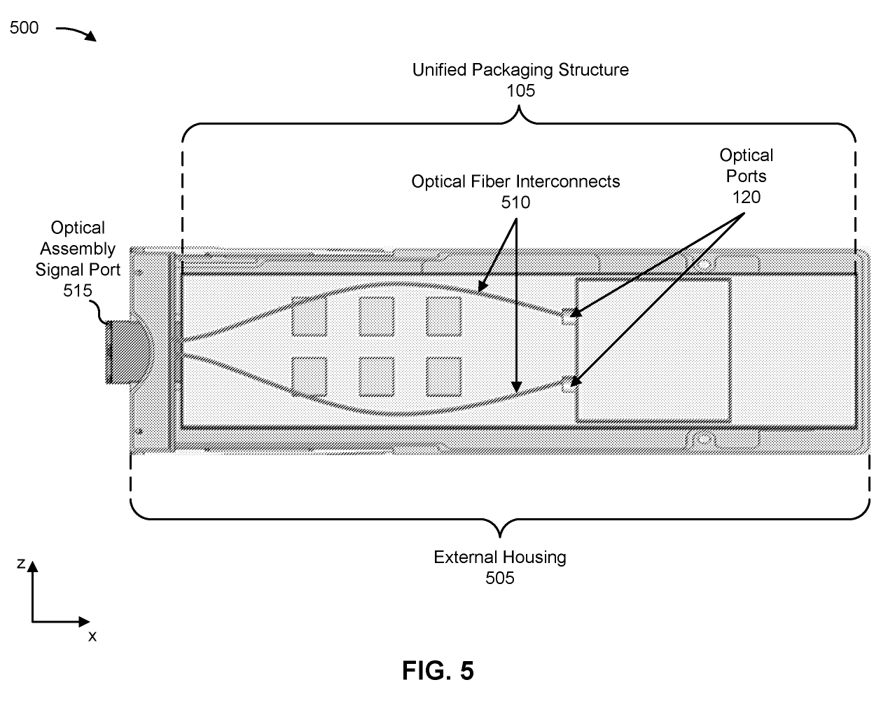

FIG. 5 shows a top-view 500 of an external housing that includes a unified packaging structure. In some implementations, the unified packaging structure 105 shown in FIG. 5 may implement or be implemented by one or more aspects of the unified packaging structure 105a and/or 105b. For example, FIG. 5 shows the unified packaging structure 105 which includes a single OSA structure 110 (e.g., unified packaging structure 105b). However, in other implementations, aspects provided herein may be implemented and/or applied for a unified packaging structure 105 that includes multiple OSA structures 110 (e.g., the unified packaging structure 105a).

As shown in FIG. 5, the unified packaging structure 105 is placed inside of an external housing 505. In other words, the external housing 505 may be an external metal work housing that encloses the unified packaging structure 105. The external housing 505 is designed to hold the unified packaging structure 105 and may be comprised of a robust metal frame that provides structural support and protection for the sensitive internal components of the unified packaging structure 105. This metal enclosure may therefore secure the unified packaging structure 105 in place, and additionally help shield the unified packaging structure 105 from external mechanical stress and/or electromagnetic interference. In some examples, the combination of the external housing 505 and the unified packaging structure 105 may be an example of an optical module structure, or a portion of an optical module structure.

Additionally, as shown in FIG. 5, integrated into the external housing 505 is an optical assembly signal port 515, which serves as a dedicated interface for optical communication (e.g., with the one or more optical chips 405 enclosed in the OSA structure 110). This optical assembly signal port 515 may be connected to the optical ports 120 of the OSA structure 110 using one or more optical fiber interconnects 510, enabling efficient transmission of optical signals between the optical chips 405 that are internal to the OSA structure 110 and external devices and/or networks. In some other implementations, the OSA structure 110 may be connected to any number of optical fiber interconnects 510 and/or a ribbon fiber interconnect. In some other implementations, the OSA structure 110 may be positioned at the front of the unified packaging structure 105, such that the OSA structure 110 is directly connected to the optical assembly signal port 515 (e.g., without any intermediary optical fiber interconnects). Accordingly, the design of the external housing 505 ensures both mechanical stability and reliable optical connectivity for the components inside.

Other examples may differ from what is shown and described with regard to FIG. 5.

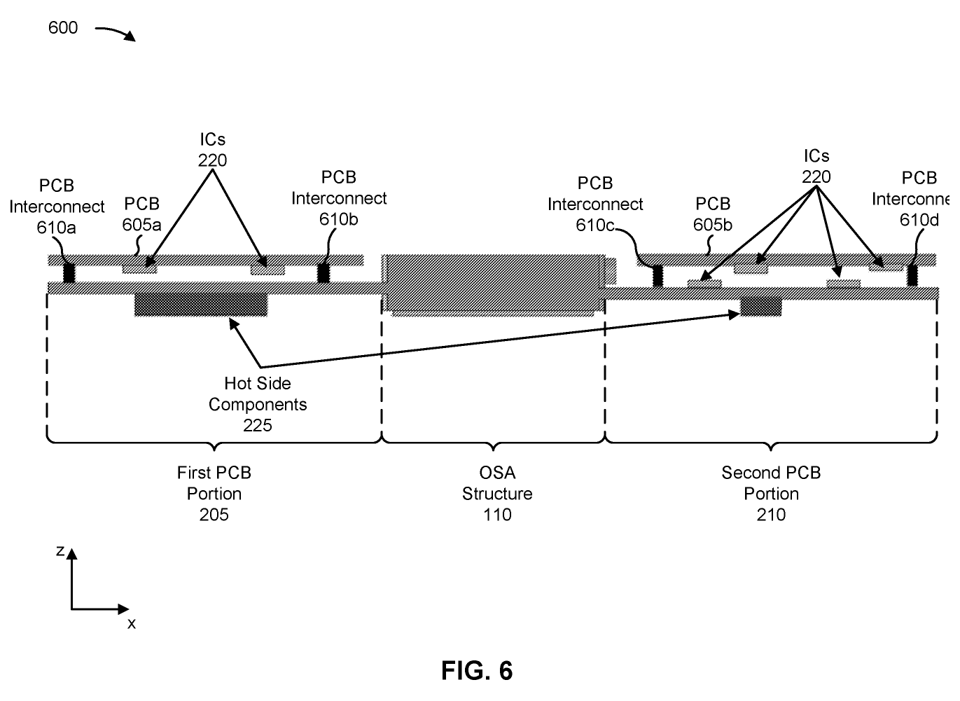

FIG. 6 shows a side-view 600 of a unified packaging structure that includes multiple PCB structures. In some implementations, the unified packaging structure 105 shown in FIG. 6 may implement or be implemented by one or more aspects of the unified packaging structure 105a and/or 105b. For example, FIG. 6 shows the unified packaging structure 105 which includes a single OSA structure 110 (e.g., unified packaging structure 105b). However, in other implementations, aspects provided herein may be implemented and/or applied for a unified packaging structure 105 that includes multiple OSA structures 110 (e.g., the unified packaging structure 105a).

As shown in FIG. 6, the unified packaging structure 105 includes PCBs 605 (e.g., PCB 605a and 605b) in addition to the PCB structure 115. The PCBs 605 may be referred to herein as “daughter” PCBs. For example, a daughter PCB (e.g., also known as a daughterboard) is a smaller circuit board that connects to the PCB structure 115 to add additional functionality or features. In some examples, the PCBs 605 may plug into and/or be electrically connected to the PCB structure 115 via one or more PCB interconnects 610 (e.g., via sockets, connectors, and/or headers, enabling modular expansion and easy upgrades without altering the PCB structure 115). For example, the PCB 605a may be electrically connected to the first PCB portion 205 via one or more first PCB interconnects 610 (e.g., PCB interconnect 610a and 610b), and the PCB 605b may be electrically connected to the second PCB portion 210 via one or more second PCB interconnects 610 (e.g., the PCB interconnect 610c and 610d). In some implementations, one or more of the PCBs 605 may be optional. For instance, in a first implementation the unified packaging structure 105 may include the PCB 605a and not include the PCB 605b, in a second implementation the unified packaging structure 105 may include the PCB 605b and not include the PCB 605a, and in a first implementation the unified packaging structure 105 may not include the PCB 605a or the PCB 605b.

In some implementations, one or more of the PCBs 605, may be comprised of a flexible circuit type material (e.g., the PCBs 605 are constructed from layers of a flexible polymer material such as those used in flexible PCB circuits). This design enables the PCBs 605 to bend and/or fold, allowing the PCBs 605 to be routed around obstacles (e.g., around the OSA structure 110). In such a case, the PCBs 605 may include one or more flexible circuits attached to and extending from or extending through the multiple sidewalls of the OSA structure 110, which can be formed or positioned to allow for the attachment of various electronic components. This flexibility may enhance the mechanical adaptability of the unified packaging structure 105 and/or support complex routing and interconnection requirements that may be challenging to achieve with rigid PCBs.

In some implementations, the layers that comprise a PCB 605 may be included in the set of layers that comprise the unified packaging structure 105. For example, PCB structure 115 may comprise a first subset of layers of the unified packaging structure 105, the OSA structure 110 may comprise a second subset of layers of the unified packaging structure 105, and a third subset of layers of the unified packaging structure 105 comprises a PCB 605 (e.g., second PCB structure) that is electrically connected to the PCB structure 115.

In some implementations, the PCBs 605 may include electrical traces 215 that electrically connect to one or more components attached to the PCBs 605. For example, as shown in FIG. 6, one or more ICs 220 may be attached to the PCBs 605a and 605b. In other implementations, however, any of the components described herein may be attached to the PCBs 605 and may be electrically connected to the PCB structure 115 via electrical traces and/or the PCB interconnects 610.

Other examples may differ from what is shown and described with regard to FIG. 6.

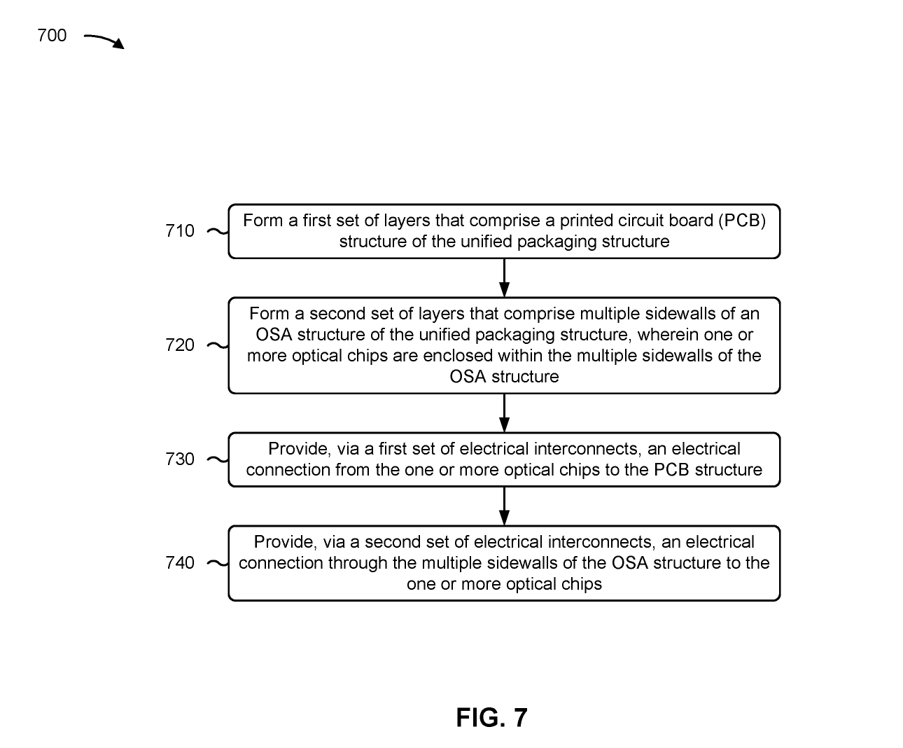

FIG. 7 is a flowchart of an example process 700 associated with manufacturing an integrated optical assembly. One or more process blocks of FIG. 7 are performed by one or more devices to manufacture a unified packaging structure (e.g., the unified packaging structure 105a and/or 105b) included in an optical assembly structure. Manufacturing equipment used to manufacture the unified packaging structure may include one or more of a computational device that implements computer-aided design (CAD) software (e.g., for layout design of the unified packaging structure), photoplotters (e.g., for producing photomasks), drilling machines (e.g., for creating holes for components and vias), laminators (for bonding layers of the unified packaging structure), etching machines (e.g., for removing conductive material to form the electrical traces 215), and silk screen printers (e.g., for applying solder masks and legends), plating systems (e.g., for adding conductive material to the unified packaging structure), pick-and-place machines (e.g., for mounting surface-mount components), reflow ovens (e.g., for soldering), die bonders (e.g., for attaching optical chips and other components to the unified packaging structure), wire bonders (e.g., for making electrical connections), and flip-chip bonders (e.g., for chip attachment techniques), active alignment and fiber alignment stations (e.g., for positioning of optical fibers and lenses), laser welding and/or soldering systems (e.g., to securely join components and/or form electrical interconnects), a 3D printing device (e.g., for printing one or more layers of the unified packaging structure) and/or dispensing systems (e.g., apply adhesives or epoxies).

As shown in FIG. 7, process 700 includes forming a first set of layers that comprise a PCB structure of the unified packaging structure (block 710). For example, the manufacturing equipment may form a first set of layers that comprise a PCB structure of the unified packaging structure, as described above.

As further shown in FIG. 7, process 700 includes forming a second set of layers that comprise multiple sidewalls of an OSA structure of the unified packaging structure, wherein one or more optical chips are subsequentially enclosed within the multiple sidewalls of the OSA structure (block 720). For example, the manufacturing equipment may form a second set of layers that comprise multiple sidewalls of an optical OSA structure of the unified packaging structure, wherein one or more optical chips are enclosed within the multiple sidewalls of the OSA structure, as described above.

As further shown in FIG. 7, process 700 includes providing, via a first set of electrical interconnects, an electrical connection from the one or more optical chips to the PCB structure (block 730). For example, the manufacturing equipment may provide, via a first set of electrical interconnects, an electrical connection from the one or more optical chips to the PCB structure, as described above.

As further shown in FIG. 7, process 700 includes providing, via a second set of electrical interconnects, an electrical connection through the multiple sidewalls of the OSA structure to the one or more optical chips (block 740). For example, the manufacturing equipment may provide, via a second set of electrical interconnects, an electrical connection through the multiple sidewalls of the OSA structure to the one or more optical chips, as described above.

Process 700 may include additional aspects, such as any single aspect or any combination of aspects described below and/or in connection with one or more other processes described elsewhere herein.

In a first aspect, process 700 includes attaching, to a high-speed portion of the PCB structure, one or more high-speed components, wherein a first subset of electrical interconnects of the first set of electrical interconnects electrically connects the one or more optical chips to the high-speed portion of the PCB structure, and attaching, to a low-speed portion of the PCB structure, one or more low-speed components, wherein a second subset of electrical interconnects of the first set of electrical interconnects electrically connects the one or more optical chips to the low-speed portion of the PCB structure.

In a second aspect, alone or in combination with the first aspect, the high-speed portion of the PCB structure is coplanar to the low-speed portion of the PCB structure.

In a third aspect, alone or in combination with one or more of the first and second aspects, the high-speed portion of the PCB structure is not coplanar to the low-speed portion of the PCB structure, and wherein the high-speed portion of the PCB structure comprises a first PCB stack from the first set of layers and the low-speed portion of the PCB structure comprises a second PCB stack from the first set of layers.

In a fourth aspect, alone or in combination with one or more of the first through third aspects, process 700 includes forming a third set of layers a third set of layers that comprises a second PCB structure that is electrically connected to the PCB structure.

In a fifth aspect, alone or in combination with one or more of the first through fourth aspects, process 700 includes forming on a top layer of the second set of layers, a lid that is part of the OSA structure, and forming, on a bottom layer of the second set of layers or a bottom layer of the first set of layers, a base that is part of the OSA structure, wherein the lid, the base, and the multiple sidewalls define a housing that encloses the one or more optical chips.

In a sixth aspect, alone or in combination with one or more of the first through fifth aspects, the lid and the base are comprised of one or more of a metal or a metal alloy.

In a seventh aspect, alone or in combination with one or more of the first through sixth aspects, the one or more optical chips are attached to a carrier, the carrier is attached to a TEC, and the TEC that is attached to the base.

In an eighth aspect, alone or in combination with one or more of the first through seventh aspects, the first set of layers comprises one or more of a polymer material, an LTCC material, an HTCC material, a thermoplastic material, or a conductive tracking material.

In a ninth aspect, alone or in combination with one or more of the first through eighth aspects, the second set of layers comprises one or more of a polymer material, an LTCC material, an HTCC material, a thermoplastic material, a conductive tracking material, a metal, or a metal alloy.

In a tenth aspect, alone or in combination with one or more of the first through ninth aspects, the second set of layers is formed above the first set of layers.

In an eleventh aspect, alone or in combination with one or more of the first through tenth aspects, the first set of layers is between at least a first portion of the second set of layers and a second portion of the second set of layers.

In a twelfth aspect, alone or in combination with one or more of the first through eleventh aspects, the first set of layers extend outwardly from the multiple sidewalls in a plane that is perpendicular to the multiple sidewalls.

In a thirteenth aspect, alone or in combination with one or more of the first through twelfth aspects, the second set of layers comprise a single layer that defines the multiple sidewalls of the OSA structure.

In a fourteenth aspect, alone or in combination with one or more of the first through thirteenth aspects, the second set of layers comprises multiple stacked layers that define the multiple sidewalls of the OSA structure.

In a fifteenth aspect, alone or in combination with one or more of the first through fourteenth aspects a sidewall of the multiple sidewalls includes at least one optical port, wherein the at least one optical port connects an optical signal to at least one optical chip of the one or more optical chips.

In a sixteenth aspect, alone or in combination with one or more of the first through fifteenth aspects, the at least one optical port includes an optical fiber that facilitates the optical signal through the sidewall to the at least one optical chip.

In a seventeenth aspect, alone or in combination with one or more of the first through sixteenth aspects, the first set of electrical interconnects comprise one or more of one or more wire bonds, one or more flexible circuits, or one or more flip chip solders.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature’s relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical module structure, comprising:
a unified packaging structure that comprises a set of layers;
a first subset of layers of the set of layers comprising a printed circuit board (PCB) structure;
a second subset of layers of the set of layers comprising multiple sidewalls of an optical sub-assembly (OSA) structure; and
one or more optical chips enclosed within the multiple sidewalls of the OSA structure, wherein:
the one or more optical chips are electrically connected to the PCB structure via a first set of electrical interconnects, and
the PCB structure providing a second set of electrical interconnects through the multiple sidewalls of the OSA structure to the one or more optical chips.

2. The optical module structure of claim 1, wherein:
a first subset of electrical interconnects of the first set of electrical interconnects electrically connects the one or more optical chips to a high-speed portion of the PCB structure that is electrically connected to one or more high-speed components of the optical module structure, and
a second subset of electrical interconnects of the first set of electrical interconnects electrically connects the one or more optical chips to a low-speed portion of the PCB structure that is electrically connected to one or more low-speed components of the optical module structure.

3. The optical module structure of claim 2, wherein the high-speed portion of the PCB structure is coplanar to the low-speed portion of the PCB structure.

4. The optical module structure of claim 2, wherein the high-speed portion of the PCB structure is not coplanar to the low-speed portion of the PCB structure, and wherein the high-speed portion of the PCB structure comprises a first PCB stack from the first subset of layers and the low-speed portion of the PCB structure comprises a second PCB stack from the first subset of layers.

5. The optical module structure of claim 1, wherein a third subset of layers of the set of layers comprises a second PCB structure that is electrically connected to the PCB structure.

6. The optical module structure of claim 1, wherein the OSA structure further comprises a lid attached to a top layer of the second subset of layers and a base attached to a bottom layer of second subset of layers or attached to a bottom layer of the first subset of layers, and wherein the lid, the base, and the multiple sidewalls define a housing that encloses the one or more optical chips.

7. The optical module structure of claim 6, wherein the lid and the base are comprised of one or more of a metal or a metal alloy.

8. The optical module structure of claim 6, wherein the one or more optical chips are attached to a carrier, the carrier is attached to a thermoelectric cooler (TEC), and the TEC that is attached to the base.

9. The optical module structure of claim 1, wherein the first subset of layers comprises one or more of a polymer material, a low-temperature co-fired ceramic (LTCC) material, a high-temperature co-fired ceramic (HTCC) material, a thermoplastic material, or a conductive tracking material.

10. The optical module structure of claim 1, wherein the second subset of layers comprises one or more of a polymer material, a low-temperature co-fired ceramic (LTCC) material, a high-temperature co-fired ceramic (HTCC) material, a thermoplastic material, a conductive tracking material, a metal, or a metal alloy.

11. The optical module structure of claim 1, wherein the second subset of layers is above the first subset of layers.

12. The optical module structure of claim 1, wherein the first subset of layers is between at least a first portion of the second subset of layers and a second portion of the second subset of layers.

13. The optical module structure of claim 1, wherein the first subset of layers extend outwardly from the multiple sidewalls in a plane that is perpendicular to the multiple sidewalls.

14. The optical module structure of claim 1, wherein the second subset of layers comprises a single layer that defines the multiple sidewalls of the OSA structure.

15. The optical module structure of claim 1, wherein the second subset of layers comprises multiple stacked layers that define the multiple sidewalls of the OSA structure.

16. The optical module structure of claim 1, wherein a sidewall of the multiple sidewalls includes at least one optical port, wherein the at least one optical port connects an optical signal to at least one optical chip of the one or more optical chips.

17. The optical module structure of claim 16, wherein the at least one optical port includes an optical fiber that facilitates the optical signal through the sidewall to the at least one optical chip.

18. The optical module structure of claim 1, wherein the first set of electrical interconnects comprise one or more of one or more wire bonds, one or more flexible circuits, or one or more flip chip solders.

19. A unified packaging structure, comprising:
a base;
a high-speed electrical interface and a low-speed electrical interface that are both formed from a first set of layers;
multiple sidewalls that are formed from a second set of layers; and
a lid, wherein:
one or more high-speed components and one or more low-speed components are attached to the first set of layers,
the base, the multiple sidewalls, and the lid form one or more optical sub-assembly (OSA) structures that enclose one or more optical chips,
the one or more optical chips are electrically connected to the first set of layers via first a set of electrical interconnects, and
the first set of layers providing a second set of electrical interconnects through the multiple sidewalls of the OSA structure to the one or more optical chips.

20. An integrated optical assembly, comprising:
a first set of layers comprising a printed circuit board (PCB) structure;
a second set of layers comprising multiple sidewalls of an optical sub-assembly (OSA) structure; and
one or more optical chips enclosed within the multiple sidewalls of the OSA structure, wherein:
the one or more optical chips are electrically connected to the PCB structure via a first set of electrical interconnects, and
the PCB structure providing a second set of electrical interconnects through the multiple sidewalls of the OSA structure to the one or more optical chips.
